(19) United States
(12) Patent Application Publication
(10) Pub. No.: US 2025/0133926 A1
(43) Pub. Date: Apr. 24, 2025

(54) DISPLAY DEVICE

(71) Applicant: Samsung Display Co., LTD., Yongin-si (KR)

(72) Inventors: YANG-HWA CHOI, Yongin-si (KR); DOO-YOUNG LEE, Yongin-si (KR); DONGHYEON KI, Yongin-si (KR); HYUK KIM, Yongin-si (KR); SANG-UK LIM, Yongin-si (KR)

(73) Assignee: Samsung Display Co., LTD., Yongin-si (KR)

(21) Appl. No.: 18/918,434

(22) Filed: Oct. 17, 2024

(30) Foreign Application Priority Data
Oct. 24, 2023 (KR) 10-2023-0143314

(51) Int. Cl. H10K 59/131; H10K 59/80

(52) U.S. Cl. CPC H10K 59/1315; H10K 59/80521

(57) ABSTRACT

A display device includes a first active pattern disposed on a substrate, a first data line disposed on the first active pattern and electrically connected to the first active pattern, a first pixel electrode disposed on the first data line, electrically connected to the first active pattern, at least partially overlapping the first data line in a plan view, and shielding the first data line, and a common electrode disposed on the first pixel electrode.

### CROSS-REFERENCE TO RELATED APPLICATION

This application claims priority to and benefits of Korean Patent Application No. 10-2023-0143314 under 35 U.S.C. § 119, filed on Oct. 24, 2023, the content of which in its entirety is incorporated herein by reference.

### BACKGROUND

### 1. Technical Field

The disclosure relates to a display device. More specifically, the disclosure relates to the display device that provides visual information.

### 2. Description of the Related Art

As information technology develops, the importance of display devices, which are a connecting medium between users and information, is emerging. Accordingly, the use of display devices such as liquid crystal display devices, organic light emitting display devices, and plasma display devices is increasing. For example, a display device may include one or more pixels, each of which includes at least one transistor, at least one capacitor, and at least one light emitting diode.

### SUMMARY

Embodiments provide a display device with improved display quality.

The technical objectives to be achieved by the disclosure are not limited to those described herein, and other technical objectives that are not mentioned herein would be clearly understood by a person skilled in the art from the description of the disclosure.

A display device according to an embodiment of the disclosure may include a first active pattern disposed on a substrate, a first data line disposed on the first active pattern and electrically connected to the first active pattern, and a first data line disposed on the first active pattern and electrically connected to the first active pattern, a first pixel electrode disposed on the first data line, connected to the first data line, at least partially overlapping the first data line in a plan view, and shielding the first data line, and a common electrode disposed on the first pixel electrode.

In an embodiment, the display device may further include a second active pattern disposed on the substrate, a second data line disposed on the second active pattern, spaced apart from the first data line in a first direction, and electrically connected to the second active pattern, and a second pixel electrode disposed on the second data line, electrically connected to the second active pattern, at least partially overlapping the second data line in a plan view, and shielding the second data line. The first pixel electrode and the second pixel electrode may be arranged in a stripe structure.

In an embodiment, the first pixel electrode and the second pixel electrode may be arranged in a stripe structure in the first direction.

In an embodiment, each of the first pixel electrode and the second pixel electrode may have a long width in a second direction intersecting the first direction.

In an embodiment, the common electrode may be a plate electrode.

In an embodiment, the first data line and the second data line may extend in a second direction intersecting the first direction.

In an embodiment, the display device may further include driving voltage lines electrically connected to the first pixel electrode and the second pixel electrode, first common voltage lines electrically connected to the common electrode and extending in the first direction, and second common voltage lines electrically connected to the electrode and extending in the second direction.

A display device according to another embodiment of the disclosure may include a first active pattern disposed on a substrate, a first data line disposed on the first active pattern and electrically connected to the first active pattern, a first shield portion disposed on the first data line, at least partially overlapping the first data line in a plan view, shielding the first data line, and a common electrode disposed on the first shield portion.

In an embodiment, the display device may further include a second active pattern disposed on the substrate, a second data line disposed on the second active pattern, spaced apart from the first data line in a first direction, and electrically connected to the second active pattern, and a second shield portion disposed on the second active pattern, at least partially overlapping the second data line in a plan view, and shielding the second data line.

In an embodiment, the display device may further include a first pixel electrode disposed on the first data line and electrically connected to the first active pattern, and a second pixel disposed on the second data line and electrically connected to the second active pattern. The first pixel electrode and the second pixel electrode may be arranged in a stripe structure.

In an embodiment, the first pixel electrode and the second pixel electrode may be arranged in a stripe structure in the first direction.

In an embodiment, each of the first pixel electrode and the second pixel electrode may have a long width in a second direction intersecting the first direction.

In an embodiment, the first pixel electrode may overlap at least a portion of the first data line in a plan view and shield the first data line.

In an embodiment, the first data line, the first pixel electrode, the first shield portion, and the common electrode may overlap each other.

In an embodiment, the second pixel electrode may overlap at least a portion of the second data line in a plan view and shield the second data line.

In an embodiment, the first data line and the second data line may extend in a second direction intersecting the first direction.

In an embodiment, the first shield portion may be disposed below the first pixel electrode in a cross-sectional view.

In an embodiment, the second shield portion may be disposed below the second pixel electrode in a cross-sectional view.

In an embodiment, the display device may further include a pixel defining layer disposed between the first pixel electrode and the second pixel electrode, and the first shield portion may be disposed on the pixel defining layer.

In an embodiment, the display device may further include a pixel defining layer disposed between the first pixel electrode and the second pixel electrode, and the second shield portion may be disposed on the pixel defining layer.

Accordingly, by disposing the pixel electrode between the data line and the common electrode, the data line, the common electrode, and the pixel electrode may overlap in a plan view. The pixel electrode may prevent a parasitic capacitor from being formed between the common electrode and the data line, and problems such as crosstalk may be improved.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a schematic perspective view showing a display device according to an embodiment of the disclosure.

FIG. 2 is a schematic diagram for explaining the display device shown in FIG. 1.

FIG. 3 is a schematic diagram of an equivalent circuit for explaining a pixel included in the display device of FIG. 2.

FIG. 4 is a schematic cross-sectional view showing each pixel of the display device according to embodiments of the disclosure.

FIG. 5 is a schematic enlarged plan view of area A of FIG. 2.

FIG. 6 is a schematic enlarged plan view of some of the pixels arranged in the display panel of FIG. 2.

FIG. 7 is a schematic cross-sectional view showing an embodiment taken along line I-I′ of FIG. 5.

FIG. 8 is a schematic cross-sectional view showing another embodiment taken along line I-I′ of FIG. 5.

FIG. 9 is a schematic cross-sectional view showing still another embodiment taken along line I-I′ of FIG. 5.

### DETAILED DESCRIPTION OF THE EMBODIMENTS

Illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. Additionally, the third direction D3 may be the normal direction of the plane. That is, the third direction D3 may be perpendicular to the plane formed by the first direction D1 and the second direction D2.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

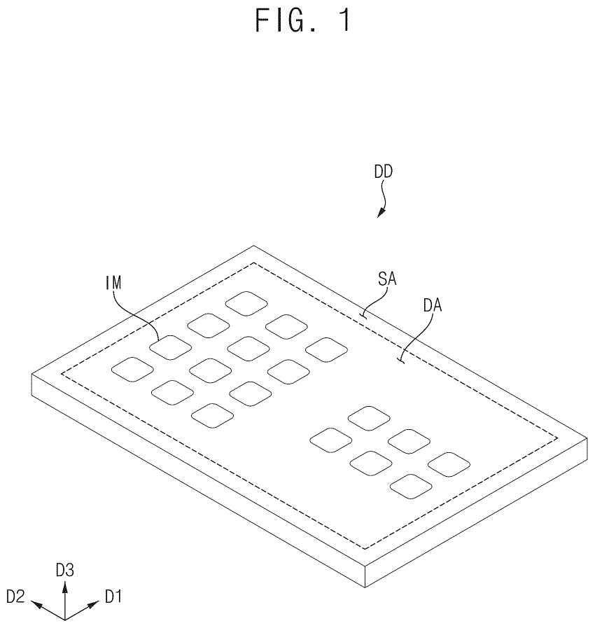

FIG. 1 is a schematic perspective view showing a display device according to an embodiment of the disclosure.

Referring to FIG. 1, a display device DD may include a display area DA and a peripheral area SA. The display area DA may be surrounded by the peripheral area SA.

The display area DA may be an area that may display an image by generating light or adjusting the transmittance of light provided from an external light source. The peripheral area SA may be an area that does not display an image. However, embodiments of the disclosure are not limited thereto, and at least a portion of the peripheral area SA may display an image.

The display area DA may display one or more images IM. Users may receive information from the display device DD through the images IM.

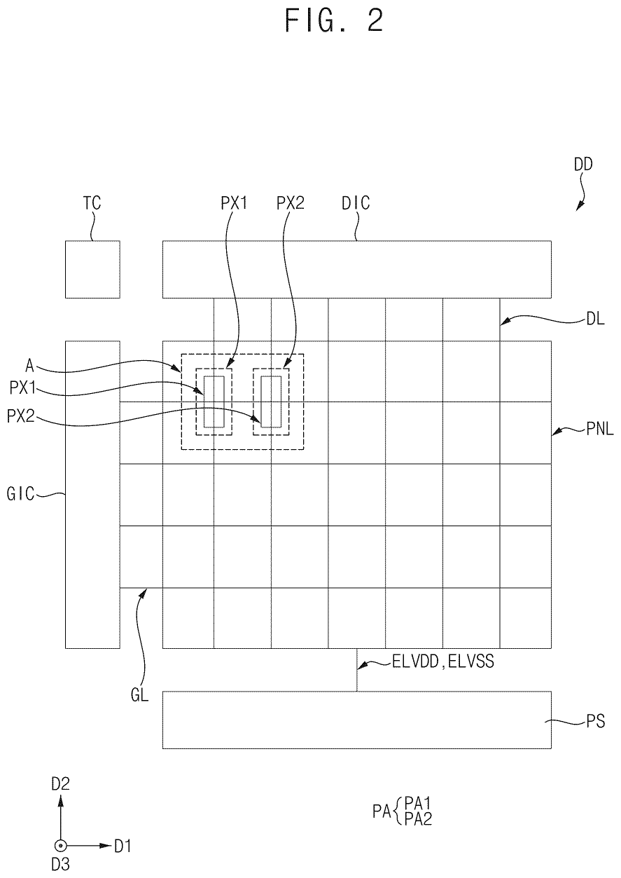

FIG. 2 is a schematic diagram for explaining the display device shown in FIG. 1.

Referring to FIG. 2, the display device DD may include a display panel PNL, a data driver DIC, data lines DL, a gate driver GIC, gate lines GL, a control portion TC, and/or a power driving portion PS.

One or more pixel areas PA may be located on the display panel PNL. The pixel areas PA may be repeatedly arranged in a matrix form in the first direction D1 and/or the second direction D2 in a plan view. For example, the pixel areas PA may include a first pixel area PA1 and a second pixel area PA2 spaced apart from the first pixel area PA1 in the first direction D1. Each of the pixel areas PA may be divided into a repetitive structure and does not mean a break in the structure.

The first pixel PX1 may be disposed in the first pixel area PA1, and the second pixel PX2 may be disposed in the second pixel area PA2. The first pixel PX1 and the second pixel PX2 may be adjacent to each other along the first direction D1. The first pixel PX1 and the second pixel PX2 may emit red, green, and blue light, respectively. However, embodiments of the disclosure are not limited thereto. The first pixel area PA1 and the second pixel area PA2 may emit a combination of red, green, and/or blue light.

The data driver DIC may be disposed to be spaced apart from the display panel PNL in the second direction D2. The data driver DIC may supply a data signal to the data lines DL in response to a data control signal provided from the control portion TC. The data lines DL may be disposed to be spaced apart in the first direction D1 and may transmit data signals to the pixels PX1 and PX2.

The gate driver GIC may be disposed to be spaced apart from the display panel PNL in a direction opposite to the first direction D1. The gate driver GIC may supply a gate signal to the gate lines GL in response to the gate control signal provided from the control portion TC. The gate lines GL may be disposed to be spaced apart in the second direction D2 and may transmit gate signals to the pixels PX1 and PX2.

The power supply portion PS may be disposed to be spaced apart from the display panel PNL in a direction opposite to the second direction D2. The power supply portion PS may supply power voltage to the pixels PX1 and PX2 of the display panel PNL. For example, the power supply portion PS may supply ELVDD and/or ELVSS to the pixels PX1 and PX2.

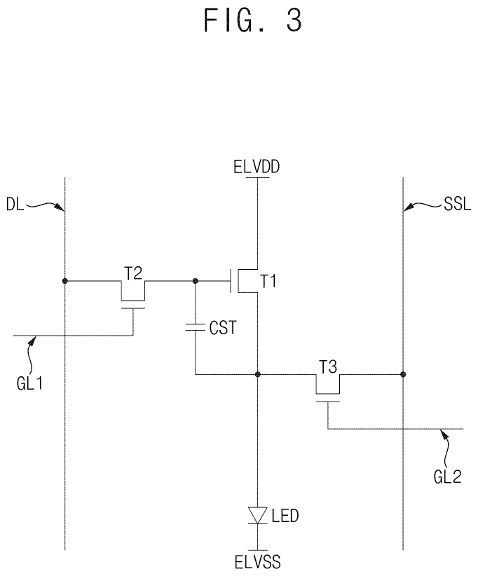

FIG. 3 is a schematic diagram of an equivalent circuit for explaining a pixel included in the display device of FIG. 2.

Referring to FIG. 3, each of the pixels PX1 and PX2 may include first, second, and third transistors T1, T2, and T3, a capacitor CST, and a light emitting diode LED.

The first transistor T1 may include a gate electrode, a first electrode, and a second electrode. The gate electrode of the first transistor T1 may be connected to the second electrode of the capacitor CST. The first electrode of the first transistor T1 may be connected to the second electrode of the third transistor T3. A driving voltage ELVDD may be applied to the second electrode of the first transistor T1.

The second transistor T2 may include a gate electrode, a first electrode, and a second electrode. The gate electrode of the second transistor T2 may be connected to the first gate line GL1. The first electrode of the second transistor T2 may be connected to the gate electrode of the first transistor T1. The second electrode of the second transistor T2 may be connected to the data lines DL.

The third transistor T3 may include a gate electrode, a first electrode, and a second electrode. The gate electrode of the third transistor T3 may be connected to the second gate line GL2. A sensing line SSL may be connected to the first electrode of the third transistor T3. The second electrode of the third transistor T3 may be connected to the first electrode of the first transistor T1.

The capacitor CST may include a first electrode and a second electrode. The first electrode of the capacitor CST may be connected to the second electrode of the third transistor T3. The second electrode of the capacitor CST may be connected to the gate electrode of the first transistor T1.

The light emitting diode LED may include a first electrode and a second electrode. The first electrode of the light emitting diode LED may be connected to the first electrode of the first transistor T1. The second electrode of the light emitting diode LED may be connected to a common voltage ELVSS.

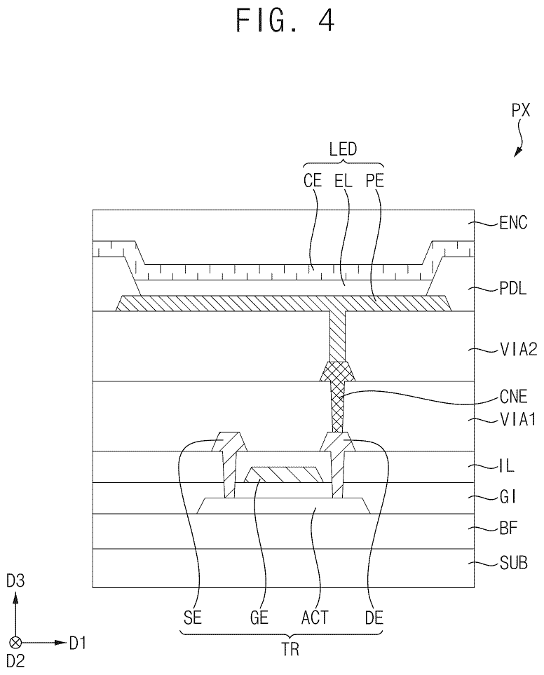

FIG. 4 is a schematic cross-sectional view showing each pixel of the display device according to embodiments of the disclosure.

Referring to FIGS. 1 and 4, the pixel may include a substrate SUB, a buffer layer BF, a gate insulating layer GI, a transistor TR, an interlayer insulating layer IL, a connection electrode CNE, a first via layer VIA1, a second via layer VIA2, the light emitting diode LED, a pixel defining layer PDL, and/or an encapsulation layer ENC.

The transistor TR may include an active layer (or active pattern) ACT, a gate electrode GE, a source electrode SE, and a drain electrode DE. The light emitting diode LED may include a pixel electrode PE, a light emitting layer EL, and a common electrode CE.

The substrate SUB may include, e.g., a glass substrate, a metal substrate, a plastic substrate, etc. However, embodiments of the disclosure are not limited thereto, and the substrate SUB may be an inorganic layer, an organic layer, or a composite material layer.

The buffer layer BF may be disposed on the substrate SUB. The buffer layer BF may be disposed on the substrate SUB. The buffer layer BF may prevent impurities such as oxygen and moisture from penetrating into the upper portion of the substrate SUB. The buffer layer BF may include, e.g., an inorganic insulating material. In an embodiment, the buffer layer BF may be formed entirely in the display area DA and the peripheral area SA in FIG. 1.

The active layer ACT may be disposed on the buffer layer BF. The active layer ACT may include, e.g., an oxide semiconductor, a silicon semiconductor, an organic semiconductor, etc. For example, the oxide semiconductor may include at least one oxide from indium (In), gallium (Ga), tin (Sn), zirconium (Zr), vanadium (V), hafnium (Hf), cadmium (Cd), germanium GE, chromium (Cr), titanium (Ti), and zinc (Zn). The silicon semiconductor may include amorphous silicon, polycrystalline silicon, etc. The active layer ACT may include a source region, a drain region, and a channel region located between the source region and the drain region.

The gate insulating layer GI may be disposed on the buffer layer BF. Specifically, the gate insulating layer GI may cover (or overlap) the active layer ACT on the buffer layer BF. The gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may overlap the channel region of the active layer ACT. The gate electrode GE may include a conductive material such as a metal, alloy, conductive metal nitride, conductive metal oxide, or transparent conductive material. Examples of the conductive materials that may be used in the gate electrode GE may include gold (Au), silver (Ag), aluminum (Al), platinum (Pt), nickel (Ni), titanium (Ti), and palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. Optionally, the gate electrode GE may have a single-layer structure or a multi-layer structure including one or more conductive layers.

An interlayer insulating layer IL may be disposed on the gate electrode GE. The interlayer insulating layer IL may cover (or overlap) the gate electrode GE on the gate insulating layer GI. The interlayer insulating layer IL may include an inorganic insulating material. In an embodiment, the interlayer insulating layer IL may be entirely disposed in the display area DA and the peripheral area SA.

The source electrode SE and the drain electrode DE may be disposed on the interlayer insulating layer IL. The source electrode SE and the drain electrode DE may be respectively connected to the active layer ACT. Each of the source electrode SE and the drain electrode DE may include a conductive material.

The first via layer VIA1 may be disposed on the source electrode SE and the drain electrode DE. The first via layer VIA1 may cover the source electrode SE and the drain electrode DE on the interlayer insulating layer IL. The first via layer VIA1 may include, e.g., an organic insulating material. In an embodiment, the first via layer VIA1 may be formed only in the display area DA and a portion of the peripheral area SA adjacent to the display area DA.

The connection electrode CNE may be disposed on the first via layer VIAL. The connection electrode CNE may transmit the signal transmitted from the transistor TR to the light emitting diode LED. The connection electrode CNE may include metal, alloy, metal nitride, conductive metal oxide, transparent conductive material, etc. These may be used alone or in combination with each other. However, embodiments of the disclosure are not limited thereto.

The second via layer VIA2 may be disposed on the connection electrode CNE. The second via layer VIA2 and the first via layer VIA1 may include substantially a same material.

The pixel electrode PE may be disposed on the second via layer VIA2. The pixel electrode PE may include a conductive material. The pixel electrode PE may be connected to the drain electrode DE through the connection electrode CNE formed in the first via layer VIAL. Accordingly, the pixel electrode PE may be electrically connected to the transistor TR.

The pixel defining layer PDL may be disposed on the pixel electrode PE. The pixel defining layer PDL may expose at least a portion of the pixel electrode PE. The pixel defining layer PDL may include an inorganic insulating material and/or an organic insulating material.

The light emitting layer EL may be disposed on the pixel electrode PE. The light emitting layer EL may be disposed between the pixel defining layers PDL. Specifically, the light emitting layer EL may be disposed in an opening defined by the pixel defining layer PDL. The light emitting layer EL may include at least one of organic light emitting material and/or quantum dots. However, embodiments of the disclosure are not limited thereto.

The common electrode CE may be disposed on the light emitting layer EL. The common electrode CE may also be disposed on the pixel defining layer PDL. The common electrode CE may include a conductive material. For example, the common electrode CE may transmit an ELVSS signal.

In an embodiment, the common electrode CE may be a plate electrode that covers (or overlaps) the entire display area DA. For example, the common electrode CE may be an electrode disposed in the first direction D1 and the second direction D2 and electrically connected.

The encapsulation layer ENC may be disposed on the common electrode CE. The encapsulation layer ENC may include at least one inorganic encapsulation layer and/or at least one organic encapsulation layer. In an embodiment, the inorganic encapsulation layer and the organic encapsulation layer may be alternately disposed.

For example, the organic encapsulation layer may include a cured polymer such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, titanium oxide, etc.

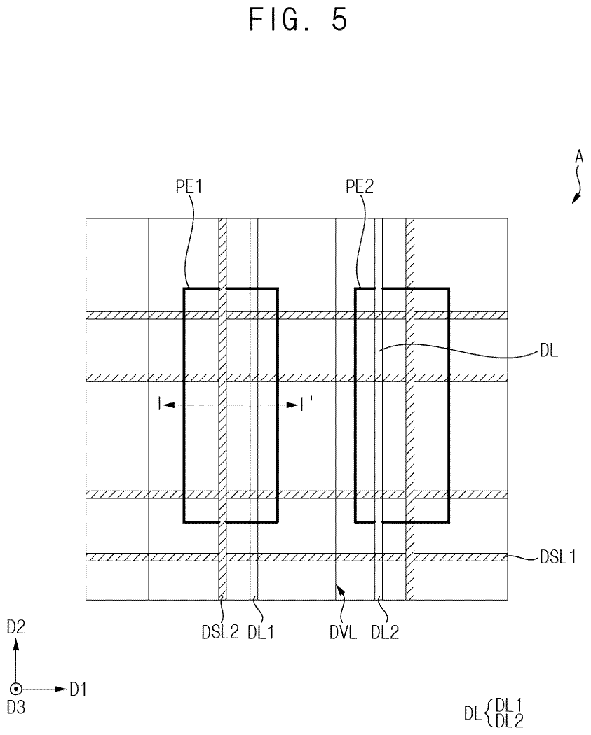

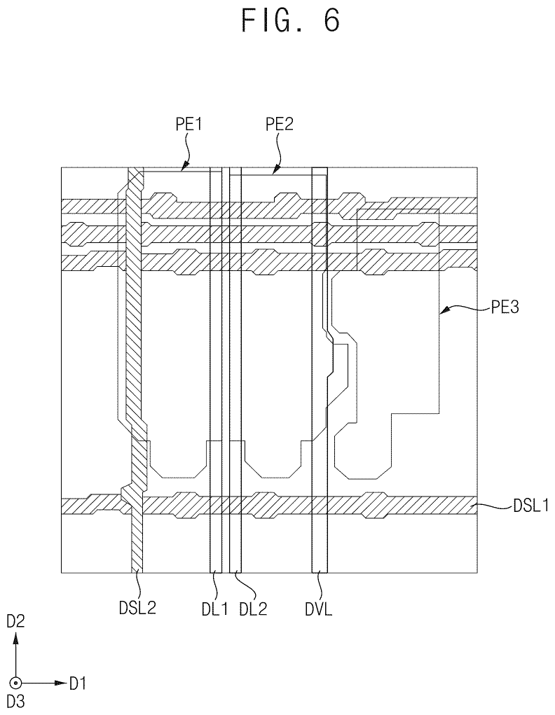

FIG. 5 is a schematic enlarged plan view of area A of FIG. 2. FIG. 6 is a schematic enlarged plan view of some of the pixels arranged in the display panel of FIG. 2. Specifically, FIG. 6 is a schematic enlarged plan view of pixels including the first pixel electrode PE1 and the second pixel electrode PE2 included in FIG. 5, as well as the third pixel electrode PE3 and metal lines. For example, FIG. 6 is a plan view specifically showing the arrangement of pixel electrodes, metal wiring, etc.

Referring to FIG. 2, FIG. 5, and FIG. 6, the first pixel electrode PE1 and the second pixel electrode PE2 may be disposed to be spaced apart in the first direction D1 in the first pixel area PA1 and the second pixel area PA2, respectively.

In an embodiment, the first pixel electrode PE1 and the second pixel electrode PE2 may have a stripe structure in the first direction D1. For example, the first pixel electrode PE1 and the second pixel electrode PE2 may be arranged side by side along the first direction D1. Optionally, in case that a third pixel electrode PE3 is disposed as shown in FIG. 6, the third pixel electrode PE3 may be arranged in a stripe structure in the first direction D1 similar to the first pixel electrode PE1 and the second pixel electrode PE2.

In an embodiment, the first pixel electrode PE1 and the second pixel electrode PE2 may have a rectangular shape. For example, the first pixel electrode PE1 and the second pixel electrode PE2 may have a rectangular shape with a long width in the second direction D2. However, embodiments of the disclosure are not limited thereto. The first pixel electrode PE1 and the second pixel electrode PE2 may have various shapes, such as diamond-shaped or circular.

A data line DL may be disposed below each of the first pixel electrode PE1 and the second pixel electrode PE2. For example, a first data line DL1 may be disposed below the first pixel electrode PE1, and a second data line DL2 may be disposed below the second pixel electrode PE2. For example, the first pixel electrode PE1 may overlap the first data line DL1 in a plan view, and the second pixel electrode PE2 may overlap the second data line DL2 in a plan view.

In an embodiment, the first data line DL1 and the second data line DL2 may extend in the second direction D2. For example, the first data line DL1 and the second data line DL2 may extend in the direction in which the pixel electrodes PE1 and PE2 have a long width. However, embodiments of the disclosure are not limited thereto.

In an embodiment, the first pixel electrode PE1 may at least partially overlap the first data line DL1 in a plan view. For example, the first pixel electrode PE1 may be disposed to overlap in a plan view between the first data line DL1 and the common electrode CE, and the first pixel electrode PE1 may shield the first data line DL1. Accordingly, the first pixel electrode PE1 may prevent a parasitic capacitor from being formed between the first data line DL1 and the common electrode (e.g., the common electrode CE in FIG. 4).

In an embodiment, the second pixel electrode PE2 may at least partially overlap the second data line DL2 in a plan view. For example, the second pixel electrode PE2 may be disposed to overlap in a plan view between the second data line DL2 and the common electrode CE, and the second pixel electrode PE2 may shield the second data line DL2. Accordingly, the second pixel electrode PE2 may prevent a parasitic capacitor from being formed between the second data line DL2 and the common electrode (e.g., the common electrode CE in FIG. 4).

First common voltage lines DSL1 extending in the first direction D1 and second common voltage lines DSL2 extending in the second direction D2 may be disposed below each of the first pixel electrode PE1 and the second pixel electrode PE2. For example, the first common voltage lines DSL1 and the second common voltage lines DSL2 may be disposed in a mesh structure along the first direction D1 and the second direction D2, respectively. The first common voltage lines DSL1 and the second common voltage lines DSL2 may be electrically connected. The first common voltage lines DSL1 and the second common voltage lines DSL2 may be electrically connected to the common electrode (e.g., the common electrode CE in FIG. 4).

In an embodiment, the number of first common voltage lines DSL1 may be greater than the number of second common voltage lines DSL2. For example, the first common voltage lines DSL1 and the second common voltage lines DSL2 may be disposed at a ratio of 2:1. However, embodiments of the disclosure are not limited thereto.

In an embodiment, the first pixel electrode PE1 and the second pixel electrode PE2 may be electrically connected to the first common voltage lines DSL1 and the second common voltage lines DSL2, and a common voltage (e.g., ELVSS) may be applied.

Driving voltage lines DVL extending in the second direction D2 may be further disposed below each of the first pixel electrode PE1 and the second pixel electrode PE2. The driving voltage lines DVL may extend in the second direction D2.

In an embodiment, the first common voltage lines DSL1, the second common voltage lines DSL2, and the driving voltage lines DVL may have a mesh structure. By arranging the first common voltage lines DSL1, the second common voltage lines DSL2, and the driving voltage lines DVL in a mesh structure, and arranging the number of the first common voltage lines DSL1 more than the driving voltage lines DVL, the resistance of the first common voltage lines DSL1 may be lowered and the occurrence of crosstalk may be reduced. For example, the first common voltage lines DSL1 and the driving voltage lines DVL may be arranged in a ratio of about 2:1 or 3:1. However, embodiments of the disclosure are not limited thereto.

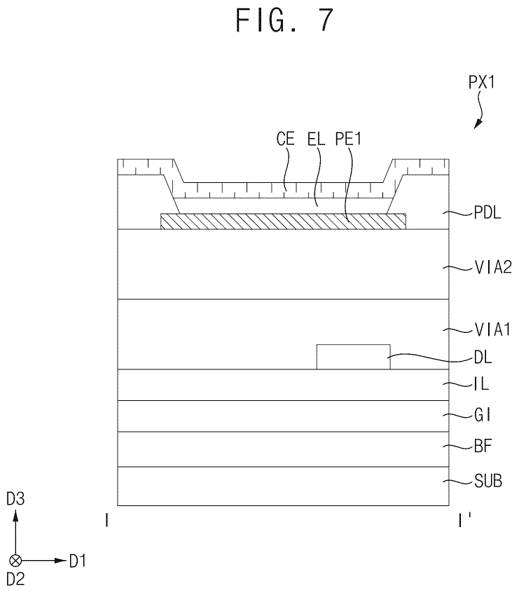

FIG. 7 is a schematic cross-sectional view showing an embodiment taken along line I-I′ of FIG. 5. For example, FIG. 7 shows a cross-sectional view of the first pixel electrode PE1 of FIG. 5 taken along the first direction D1. A cross-sectional view of the second pixel electrode PE2 in the first direction D1 may also be the same as that shown in FIG. 7. FIG. 7 is illustrated mainly the first data line DL1, the first pixel electrode PE1, and the common electrode CE.

Referring to FIG. 7, the first data line DL1 may be disposed in the first via layer VIAL. Specifically, the first data line DL1 may be disposed on the interlayer insulating layer IL. The first via layer VIA1 may be disposed on the inorganic layer IL and may cover the first data line DL1.

In an embodiment, the first data line DL1 may overlap the first pixel electrode PE1 in a plan view. Specifically, the first pixel electrode PE1 may be disposed between the first data line DL1 and the common electrode CE in a cross-sectional view. Accordingly, a parasitic capacitor may be prevented from being formed between the first data line DL1 and the common electrode CE. For example, as shielding the first data line DL1 and the common electrode CE by the first pixel electrode PE1, coupling between the data signal and the ELVSS signal may be prevented.

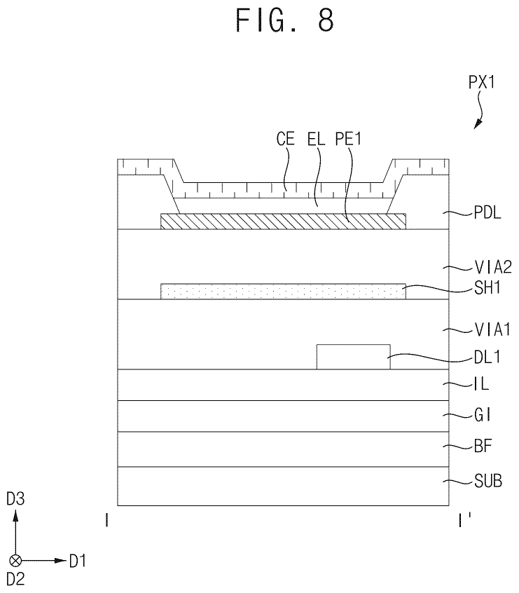

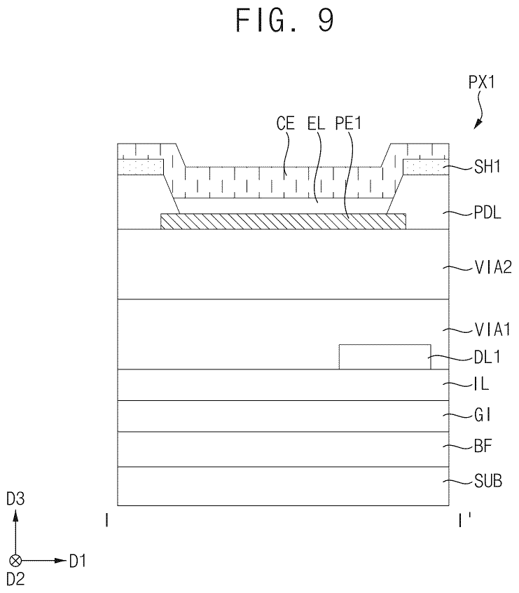

FIG. 8 is a schematic cross-sectional view showing another embodiment taken along line I-I′ of FIG. 5, and FIG. 9 is a schematic cross-sectional view showing still another embodiment taken along line I-I′ of FIG. 5. For example, FIGS. 8 and 9 show cross-sectional views of the first pixel electrode PE1 taken in the first direction D1. A cross-sectional view of the second pixel electrode PE2 in the first direction D1 may also be the same as the drawings shown in FIGS. 8 and 9. Therefore, a first shield portion SH1 described in FIGS. 8 and 9 may be substantially the same as a second shield portion obtained when the second pixel electrode PE2 is taken in the first direction D1. For example, the shield portion SH may include the first shield portion SH1 and the second shield portion.

Referring to FIGS. 8 and 9, the first pixel PE1 may include the first shield portion SH1 in cross-section. The first shield portion SH1 may be disposed between the first data line DL1 and the common electrode CE in a cross-sectional view. For example, the first shield portion SH1 may be disposed to overlap the first data line DL1 and/or the common electrode CE in a plan view. For example, the shield portion SH may include the first shield portion SH1 and/or the second shield portion. The shield portion SH may include a metal material and/or an inorganic material.

In an embodiment, the first shield portion SH1 may overlap the first data line DL1, the first pixel electrode PE1, and the common electrode CE in a plan view. Likewise, the second shield portion may overlap the second data line (e.g., the second data line DL2 in FIG. 5), the second pixel electrode PE2, and the common electrode CE in a plan view.

In an embodiment, as shown in FIG. 8, the first shield portion SH1 may be disposed in the second via layer VIA2. Specifically, the first shield SH1 may be disposed on the first via layer VIA1, and the second via layer VIA2 may cover the first shield SH1. That is, each of the first shield portion SH1 and the second shield portion may be disposed below the first pixel electrode PE1 and the second pixel electrode PE2. As the first shield portion SH1 is disposed in the second via layer VIA2 to shield the first data line DL1 and the common electrode CE, parasitic capacitors formed between the first data line DL1 the common electrodes CE may be prevented.

In an embodiment, as shown in FIG. 9, the first shield portion SH1 may be disposed on the pixel defining layer PDL. Specifically, the first shield portion SH1 may be disposed between the pixel defining layer PDL and the common electrode CE in a cross-sectional view. For example, the first shield portion SH1 may at least partially overlap the first data line DL1 and/or the common electrode CE in a plan view. As the first shield portion SH1 is disposed on the pixel defining layer PDL to shield the first data line DL1 and the common electrode CE, parasitic capacitors formed between the first data line DL1 and the common electrode CE may be prevented.

As seen in FIGS. 1 and 9, by disposing the pixel electrode PE between the data line DL and the common electrode CE, the data line DL, the common electrode CE, and the pixel electrodes PE may overlap in a plan view. The pixel electrode PE may prevent a parasitic capacitor from being formed between the common electrode CE and the data line DL, thereby improving problems such as crosstalk.

The disclosure may be applied to the display device and the electronic device including a same. For example, the disclosure may be applied to high-resolution smartphones, mobile phones, smart pads, smart watches, tablet PCs, vehicle navigation systems, televisions, computer monitors, laptops, etc.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first active pattern disposed on a substrate;
a first data line disposed on the first active pattern and electrically connected to the first active pattern;
a first pixel electrode disposed on the first data line, electrically connected to the first active pattern, at least partially overlapping the first data line in a plan view, and shielding the first data line; and
a common electrode disposed on the first pixel electrode.

2. The display device of claim 1, further comprising:
a second active pattern disposed on the substrate;
a second data line disposed on the second active pattern, spaced apart from the first data line in a first direction, and electrically connected to the second active pattern; and
a second pixel electrode disposed on the second data line, electrically connected to the second active pattern, at least partially overlapping the second data line in a plan view, and shielding the second data line,
wherein the first pixel electrode and the second pixel electrode are arranged in a stripe structure.

3. The display device of claim 2, wherein the first pixel electrode and the second pixel electrode are arranged in a stripe structure in the first direction.

4. The display device of claim 2, wherein each of the first pixel electrode and the second pixel electrode has a long width in a second direction intersecting the first direction.

5. The display device of claim 1, wherein the common electrode is a plate electrode.

6. The display device of claim 2, wherein the first data line and the second data line extend in a second direction intersecting the first direction.

7. The display device of claim 2, further comprising:
driving voltage lines electrically connected to the first pixel electrode and the second pixel electrode;
first common voltage lines electrically connected to the common electrode and extending in the first direction; and
second common voltage lines electrically connected to the common electrode and extending in a second direction.

8. A display device comprising:
a first active pattern disposed on a substrate;
a first data line disposed on the first active pattern and electrically connected to the first active pattern;
a first shield portion disposed on the first data line, at least partially overlapping the first data line in a plan view, and shielding the first data line; and
a common electrode disposed on the first shield portion.

9. The display device of claim 8, further comprising:
a second active pattern disposed on the substrate;
a second data line disposed on the second active pattern, spaced apart from the first data line in a first direction, and electrically connected to the second active pattern; and
a second shield portion disposed on the second active pattern, at least partially overlapping the second data line in a plan view, and shielding the second data line.

10. The display device of claim 9, further comprising:
a first pixel electrode disposed on the first data line and electrically connected to the first active pattern; and
a second pixel electrode disposed on the second data line and electrically connected to the second active pattern,
wherein the first pixel electrode and the second pixel electrode are arranged in a stripe structure.

11. The display device of claim 10, the first pixel electrode and the second pixel electrode are arranged in a stripe structure in the first direction.

12. The display device of claim 10, wherein each of the first pixel electrode and the second pixel electrode has a long width in a second direction intersecting the first direction.

13. The display device of claim 10, wherein the first pixel electrode overlaps at least a portion of the first data line in a plan view and shields the first data line.

14. The display device of claim 13, wherein the first data line, the first pixel electrode, the first shield portion, and the common electrode overlap each other.

15. The display device of claim 10, wherein the second pixel electrode overlaps at least a portion of the second data line in a plan view and shields the second data line.

16. The display device of claim 9, wherein the first data line and the second data line extend in a second direction intersecting the first direction.

17. The display device of claim 10, wherein the first shield portion is disposed below the first pixel electrode in a cross-sectional view.

18. The display device of claim 10, wherein the second shield portion is disposed below the second pixel electrode in a cross-sectional view.

19. The display device of claim 10, further comprising:
a pixel defining layer disposed between the first pixel electrode and the second pixel electrode,
wherein the first shield portion is disposed on the pixel defining layer.

20. The display device of claim 10, further comprising:
a pixel defining layer disposed between the first pixel electrode and the second pixel electrode,
wherein the second shield portion is disposed on the pixel defining layer.
